(19) United States
(12) Patent Application Publication
(10) Pub. No.: US 2008/0160680 A1
(43) Pub. Date: Jul. 3, 2008

(54) METHODS OF FABRICATING SHIELD PLATES FOR REDUCED FIELD COUPLING IN NONVOLATILE MEMORY

(76) Inventor: Jack H. Yuan, Cupertino, CA (US)

Correspondence Address: VIERRA MAGEN/SANDISK CORPORATION, 575 MARKET STREET, SUITE 2500, SAN FRANCISCO, CA, 94105, US

(21) Appl. No.: 11/617,593

(22) Filed: Dec. 28, 2006

(51) Int. Cl. H01L 21/82; H01L 21/8239

(52) U.S. Cl. 438/129; 438/266; 257/E21.645

(57) ABSTRACT

Shield plates for reduced coupling between charge storage regions in nonvolatile semiconductor memory devices, and associated techniques for forming the same, are provided. Electrical fields associated with charge stored in the floating gates or other charge storage regions of a memory device can couple to neighboring charge storage regions because of the close, and continually decreasing proximity of these regions. A shield plate can be formed adjacent to the bit line sides of floating gates that face opposing bit line sides of adjacent floating gates. Insulating layers can be formed between each shield plate and its corresponding adjacent charge storage region. The insulating layers can extend to the levels of the upper surfaces of the control gates formed above the charge storage regions. In such a configuration, sidewall fabrication techniques can be implemented to form the insulating members and shield plates. Each shield plate can be deposited and etched without complex masking to connect the control gates and shield plates. In one embodiment, the shield plates are at a floating potential.

### CROSS-REFERENCE TO RELATED APPLICATION

The following application is cross-referenced and incorporated by reference herein in its entirety:

U.S. patent application Ser. No. ______ [Attorney Docket No. SAND-01079US1], entitled “Shield Plates for Reduced Field Coupling in Non-Volatile Memory,” by Jack H. Yuan, filed on even date herewith.

### BACKGROUND OF THE INVENTION

1. Field of the Invention

Embodiments of the present disclosure are directed to high density semiconductor devices, such as nonvolatile memory, and systems and methods for isolating components in high density semiconductor devices.

2. Description of the Related Art

Semiconductor memory devices have become more popular for use in various electronic devices. For example, nonvolatile semiconductor memory is used in cellular telephones, digital cameras, personal digital assistants, mobile computing devices, non-mobile computing devices and other devices. Electrical Erasable Programmable Read Only Memory (EEPROM), including flash EEPROM, and Electronically Programmable Read Only Memory (EPROM) are among the most popular nonvolatile semiconductor memories.

Flash memory utilizes a floating gate or other charge storage region positioned above and insulated from a channel region in a semiconductor substrate. The floating gate is positioned between source and drain regions. A control gate is provided over and insulated from the floating gate. The threshold voltage of the transistor is controlled by the amount of charge that is retained on the floating gate. That is, the minimum amount of voltage that must be applied to the control gate before the transistor is turned on to permit conduction between its source and drain is controlled by the level of charge on the floating gate.

When programming an EEPROM or flash memory device, such as a NAND flash memory device, a program voltage is typically applied to the control gate and the bit line is grounded. Electrons from the channel are injected into the floating gate. When electrons accumulate in the floating gate, the floating gate becomes negatively charged and the threshold voltage of the memory cell is raised so that the memory cell is in a programmed state. More information about programming can be found in U.S. patent application Ser. No. 10/379,608, titled “Self-Boosting Technique,” filed on Mar. 5, 2003; and in U.S. patent application Ser. No. 10/629,068, titled “Detecting Over Programmed Memory,” filed on Jul. 29, 2003; both applications are incorporated herein by reference in their entirety.

Some EEPROM and flash memory devices have a floating gate that is used to store two ranges of charges and, therefore, the memory cell can be programmed/erased between two states (an erased state and a programmed state). Such a flash memory device is sometimes referred to as a binary flash memory device.

A multi-state flash memory device is implemented by identifying multiple distinct allowed/valid programmed threshold voltage ranges separated by forbidden ranges. Each distinct threshold voltage range corresponds to a predetermined value for the set of data bits encoded in the memory device.

Shifts in the apparent charge stored on a floating gate or other charge storage region can occur because of electric field coupling based on the charge stored in neighboring floating gates. This floating gate to floating gate coupling phenomena is described in U.S. Pat. No. 5,867,429, incorporated herein by reference in its entirety. A target floating gate and adjacent floating gate may include neighboring floating gates on the same bit line, neighboring floating gates on the same word line, or floating gates on neighboring bit lines and word lines and thus, diagonally adjacent from one another.

The floating gate to floating gate coupling phenomena occurs most pronouncedly between sets of adjacent memory cells that have been programmed at different times. For example, a first memory cell is programmed to add a level of charge to its floating gate that corresponds to one set of data. Subsequently, one or more adjacent memory cells are programmed to add a level of charge to their floating gates that correspond to a second set of data. After the one or more of the adjacent memory cells are programmed, the charge level read from the first memory cell appears to be different than that originally programmed, because of the effect of the programmed charge on the adjacent memory cells being coupled to the first memory cell. The coupling from adjacent memory cells can shift the apparent charge level being read from a target cell by a sufficient amount to lead to an erroneous reading of the data stored therein.

The impact of the floating gate to floating gate coupling is of greater concern for multi-state devices because in multi-state devices, the allowed threshold voltage ranges and the forbidden ranges are narrower than in binary devices. Therefore, the floating gate to floating gate coupling can result in memory cells being shifted from an allowed threshold voltage range to a forbidden range.

As memory cells continue to shrink in size, the natural programming and erase distributions of threshold voltages are expected to increase due to short channel effects, greater oxide thickness/coupling ratio variations and more channel dopant fluctuations, reducing the available separation between adjacent states. This effect is much more significant for multi-state memories than memories using only two states (binary memories). Furthermore, the reduction of the space between word lines and of the space between bit lines will also increase the coupling between adjacent floating gates.

Thus, there is a need to reduce the effects of charge coupling between floating gates and other charge storage regions in nonvolatile semiconductor memory.

### SUMMARY OF THE INVENTION

Shield plates for reduced coupling between charge storage regions in nonvolatile semiconductor memory devices, and associated techniques for forming the same, are provided. A shield plate can be formed adjacent to the bit line sides of floating gates facing opposing bit line sides of adjacent floating gates. Insulating layers can be formed between each shield plate and its corresponding adjacent charge storage region. The insulating layers can extend to the levels of the upper surfaces of the control gates formed above the charge storage regions. In such a configuration, sidewall fabrication techniques can be implemented to form the insulating members and shield plates. Each shield plate can be a deposited sidewall formed without complex masking to connect the control gates and shield plates. In one embodiment, the shield plates are at a floating potential.

In one embodiment, a method of fabricating nonvolatile memory is provided that includes forming a plurality of adjacent charge storage regions in a first direction along a substrate, forming a plurality of adjacent control gates above the charge storage regions, and forming insulating members along sides of the charge storage regions facing adjacent charge storage regions in the first direction and along sides of the control gates facing adjacent control gates in the first direction. The insulating members extend from at least the lower surface level of the floating gates to at least the upper surface level of the control gates. Conductive isolating members are formed along the insulating members such that they are insulated from the charge storage regions and control gates. In one embodiment, the isolating members are at a floating potential. In one embodiment, the isolating members are electrically connected to corresponding word lines at a portion of the word lines beyond the individual storage elements of each corresponding row or at an opening in the memory array.

In one embodiment, a nonvolatile memory system is provided that includes a plurality of adjacent charge storage regions arranged in a bit line direction above a substrate, a plurality of control gates formed above the adjacent charge storage regions, each control gate having two bit line sides substantially co-planar with the bit line sides of a corresponding charge storage region, an insulating member adjacent to each of the bit line sides of adjacent charge storage regions, and a floating conductive isolation member adjacent to each insulating member, each isolation member shielding a corresponding adjacent charge storage region. In one embodiment, the conductive isolation members can be connected with word lines formed above charge storage regions corresponding to the isolation members. The insulating members can extend from the lower surface level of the charge storage regions to the upper surface level of the control gates.

Other features, aspects, and objects of the invention can be obtained from a review of the specification, the figures, and the claims.

### BRIEF DESCRIPTION OF THE DRAWINGS

FIG. 1 is a top view of a NAND string.

FIG. 2 is an equivalent circuit diagram of the NAND string depicted in FIG. 1.

FIG. 3 is a circuit diagram depicting three NAND strings.

FIG. 4 is a two-dimensional block diagram of one embodiment of a flash memory cell that can be fabricated in accordance with one embodiment.

FIG. 5 is a three-dimensional drawing of a pair of four word line long portions of two NAND strings that can be fabricated in accordance with one embodiment.

FIG. 6 is a plan view of a portion of a NAND flash memory array in one embodiment.

FIG. 7 is a flowchart of a method for fabricating flash memory in accordance with one embodiment.

FIGS. 8A-8G depict a portion of a memory array fabricated in accordance with one embodiment.

FIG. 9 depicts a portion of a memory array fabricated in accordance with one embodiment.

FIG. 10 depicts an exemplary organization of a memory array in accordance with one embodiment.

FIG. 11 depicts an exemplary organization of a memory array in accordance with one embodiment.

FIG. 12 is a block diagram of an exemplary memory system that can be implemented in accordance with one embodiment.

FIG. 13 is a flow chart describing one embodiment of a process for programming nonvolatile memory devices.

FIG. 14 is a flow chart describing one embodiment of a process for reading nonvolatile memory devices.

### DETAILED DESCRIPTION

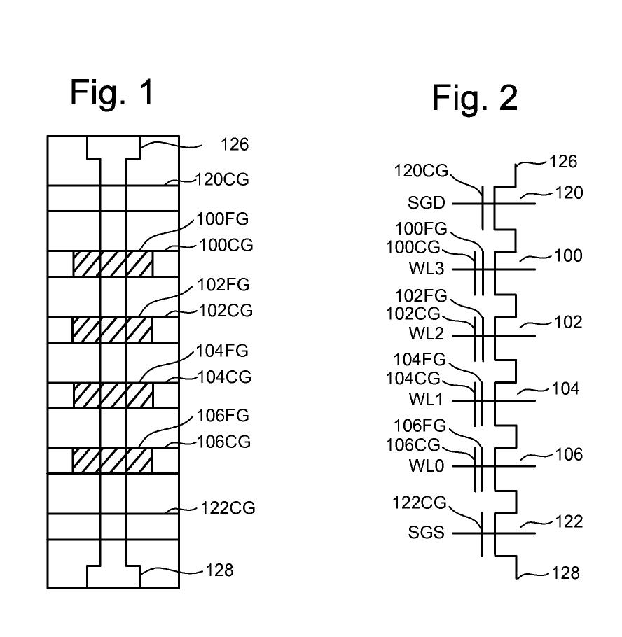

FIG. 1 is a top view showing one NAND string. FIG. 2 is an equivalent circuit thereof. Shielding and isolation techniques in accordance with embodiments are presented with respect to nonvolatile flash memory, specifically NAND type flash memory, for purposes of explanation. It will be appreciated by those of ordinary skill in the art, however, that the techniques set forth are not so limited and can be utilized in many fabrication processes to fabricate various types of integrated circuits. For example, these techniques can be used to fabricate NOR type memories or other devices where shielding is needed between neighboring charge storage regions.

The NAND string depicted in FIGS. 1 and 2 includes four transistors 100, 102, 104 and 106 in series and sandwiched between a first select gate 120 and a second select gate 122. Select gate 120 connects the NAND string to a bit line via bit line contact 126. Select gate 122 connects the NAND string to a common source line via source line contact 128. Each of the transistors 100, 102, 104 and 106 includes a control gate and a floating gate. For example, transistor 100 has control gate 100CG and floating gate 100FG. Transistor 102 includes control gate 102CG and a floating gate 102FG. Transistor 104 includes control gate 104CG and floating gate 104FG. Transistor 106 includes a control gate 106CG and a floating gate 106FG. Control gate 100CG is connected to word line WL3, control gate 102CG is connected to word line WL2, control gate 104CG is connected to word line WL1, and control gate 106CG is connected to word line WL0.

Note that although FIGS. 1 and 2 show four memory cells in the NAND string, the use of four transistors is only provided as an example. A NAND string can have less than four memory cells or more than four memory cells. For example, some NAND strings will include eight memory cells, 16 memory cells, 32 memory cells, or more.

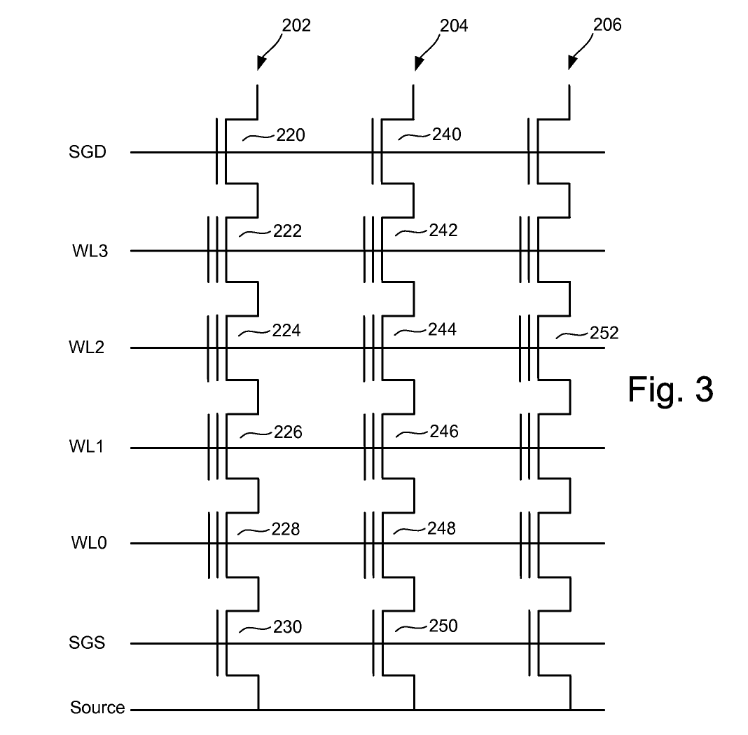

A typical architecture for a flash memory system using a NAND structure will include many NAND strings. For example, FIG. 3 shows three NAND strings 202, 204 and 206 of a memory array having many more NAND strings. Each of the NAND strings of FIG. 3 includes two select transistors and four memory cells. Each string is connected to the source line by its select transistor (e.g. select transistor 230 and select transistor 250). A selection line SGS is used to control the source side select gates. The various NAND strings are connected to respective bit lines by select transistors 220, 240, etc., which are controlled by select line SGD. Each word line (WL3, WL2, WL1 and WL0) is connected to the control gate of one memory cell on each NAND string forming a row of cells. For example, word line WL2 is connected to the control gates for memory cell 224, 244, and 252. As can be seen, each bit line and the respective NAND string comprise the columns of the array of memory cells.

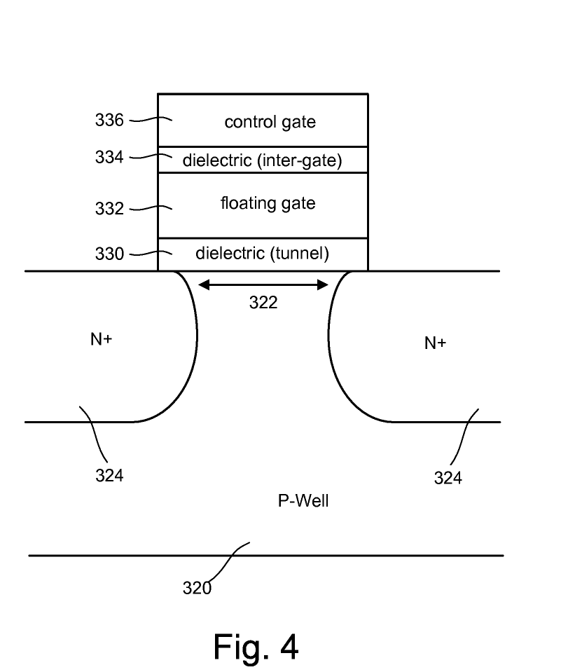

FIG. 4 is a two-dimensional block diagram of one embodiment of a flash memory cell such as those depicted in FIGS. 1-3 that can be fabricated in accordance with embodiments. The memory cell of FIG. 4 includes a triple well comprising a P-substrate, an N-well, and a P-well. The P-substrate and the N-well are not depicted in FIG. 4 in order to simplify the drawing. Within P-well 320, are N+ doped regions 324, which serve as source/drain regions for the memory cell. Whether N+ doped regions 324 are labeled as source regions or drain regions is somewhat arbitrary. In a NAND string, a source/drain region 324 will serve as a source for one memory cell and a drain for an adjacent memory cell. Therefore, the N+ doped source/drain regions 324 can be thought of as source regions, drain regions, or both.

Between N+ doped regions 324 is a channel 322. Above channel 322 is a first dielectric area or layer 330. Above dielectric layer 330 is a conductive area or layer 332 that forms a floating gate of the memory cell. The floating gate, under low-voltage operating conditions associated with read or bypass operations, is electrically insulated/isolated from channel 322 by the first dielectric layer 330. Above floating gate 332 is a second dielectric area or layer 334. Above dielectric layer 334 is a second conductive layer 336 that forms a control gate of the memory cell. In other embodiments, various layers may be interspersed within or added to the illustrated layers. For example, additional layers can be placed above control gate 336, such as a hard mask. Together, dielectric 330, floating gate 332, dielectric 332, and control gate 336 comprise a stack. An array of memory cells will have many such stacks. As used herein, the term stack can refer to the layers/areas of memory cells at different times during the fabrication process and thereafter. Thus, a stack can include more or fewer layers than depicted in FIG. 4 dependent upon which phase of fabrication the cell is in.

In one type of memory cell useful in flash EEPROM systems, a non-conductive dielectric material is used in place of a conductive floating gate to store charge in a nonvolatile manner. Such a cell is described in an article by Chan et al., “A True Single-Transistor Oxide-Nitride-Oxide EEPROM Device,” IEEE Electron Device Letters, Vol. EDL-8, No. 3, March 1987, pp. 93-95. A triple layer dielectric formed of silicon oxide, silicon nitride and silicon oxide (“ONO”) is sandwiched between a conductive control gate and a surface of a semi-conductive substrate above the memory cell channel. The cell is programmed by injecting electrons from the cell channel into the nitride, where they are trapped and stored in a limited region. This stored charge then changes the threshold voltage of a portion of the channel of the cell in a manner that is detectable. The cell is erased by injecting hot holes into the nitride. See also Nozaki et al., “A 1-Mb EEPROM with MONOS Memory Cell for Semiconductor Disk Application,” IEEE Journal of Solid-State Circuits, Vol. 26, No. 4, April 1991, pp. 497-501, which describes a similar cell in a split-gate configuration where a doped polysilicon gate extends over a portion of the memory cell channel to form a separate select transistor. The foregoing two articles are incorporated herein by reference in their entirety. The programming techniques mentioned in section 1.2 of “Nonvolatile Semiconductor Memory Technology,” edited by William D. Brown and Joe E. Brewer, IEEE Press, 1998, incorporated herein by reference, are also described in that section to be applicable to dielectric charge-trapping devices. The memory cells described in this paragraph can also be used with embodiments of the present disclosure.

Another approach to storing two bits in each cell has been described by Eitan et al., “NROM: A Novel Localized Trapping, 2-Bit Nonvolatile Memory Cell,” IEEE Electron Device Letters, vol. 21, no. 11, November 2000, pp. 543-545. An ONO dielectric layer extends across the channel between source and drain diffusions. The charge for one data bit is localized in the dielectric layer adjacent to the drain, and the charge for the other data bit localized in the dielectric layer adjacent to the source. Multi-state data storage is obtained by separately reading binary states of the spatially separated charge storage regions within the dielectric. The memory cells described in this paragraph can also be used with embodiments of the present disclosure.

When programming in tunneling-based, electrically erasable programmable read-only memory (EEPROM) or flash memory devices, a program voltage is typically applied to the control gate and the bit line is grounded. Electrons from the channel are injected into the floating gate as electrons tunnel across dielectric 330. Dielectric 330 is often referred to as a tunnel dielectric or tunnel oxide for this reason. When electrons accumulate in floating gate 332, the floating gate becomes negatively charged, and the threshold voltage of the memory cell is raised to within one of the threshold voltage ranges pre-defined to represent the storage of one or more bits of data. Typically, the program voltage applied to the control gate is applied as a series of pulses. The magnitude of the pulses is increased with each successive pulse by a pre-determined step size.

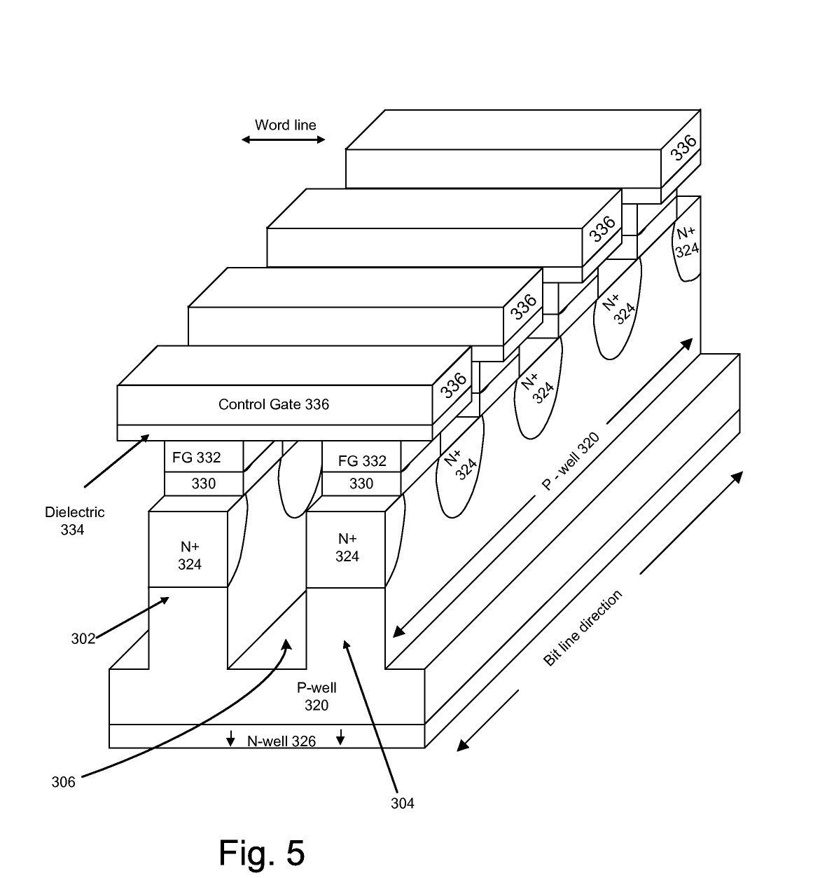

FIG. 5 is a three-dimensional block diagram of two typical NAND strings 302 and 304 that may be fabricated as part of a larger flash memory array. While FIG. 5 depicts four memory cells on strings 302 and 304, more or less than four memory cells can be used. Each of the memory cells of the NAND string has a stack as described above with respect to FIG. 4. FIG. 5 further depicts N-well 326 below P-well 320, the bit line direction along the NAND string, and the word line direction perpendicular to the NAND string or bit line direction. The P-type substrate below N-well 336 is not shown in FIG. 5. In one embodiment, the control gates form the word lines. A continuous layer of conductive layer 336 is formed which is consistent across a word line in order to provide a common word line or control gate for each device on that word line. An individual control gate layer 336 is depicted in FIG. 5 which forms a single word line for a plurality of memory cells in a row. In such a case, this layer can be considered to form a control gate for each memory cell at the point where the layer overlaps a corresponding floating gate layer 332. In other embodiments, individual control gates can be formed and then interconnected by a separately formed word line.

When fabricating a NAND-based nonvolatile memory system, including NAND strings as depicted in FIG. 5, it is important to provide electrical isolation in the word line direction between adjacent strings such as NAND strings 302 and 304. In the embodiment depicted in FIG. 5, NAND string 302 is separated from NAND string 304 by an open area or void 306. In typical NAND configurations, a dielectric material is formed between adjacent NAND strings and would be present at the position of open area 306.

Numerous techniques exist for isolating devices in the word line direction for NAND flash memory and other types of semiconductor devices. In Local Oxidation of Silicon (LOCOS) techniques, an oxide is grown or deposited on the surface of a substrate, followed by the deposition of a nitride layer over the oxide layer. After patterning these layers to expose the desired isolation areas and cover the desired active areas, a trench is etched into these layers and a portion of the substrate. An oxide is then grown on the exposed regions. Improvements to LOCOS processes have been made by employing techniques such as sidewall-masked isolation (SWAMI) to decrease encroachment into active areas. In SWAMI, a nitride is formed on the trench walls prior to forming the oxide to decrease the oxide's encroachment and formation of bird's beaks. For more details regarding these and other isolation techniques, refer to U.S. patent application Ser. No. 10/996,030, entitled “SELF-ALIGNED TRENCH FILLING WITH HIGH COUPLING RATIO,” by Jack H. Yuan, filed Nov. 23, 2004, and U.S. patent application Ser. No. 11/251,386, entitled “SELF-ALIGNED TRENCH FILLING FOR NARROW GAP ISOLOATION REGIONS,” by Jack H. Yuan, filed Oct. 14, 2005, both incorporated by reference herein in their entirety.

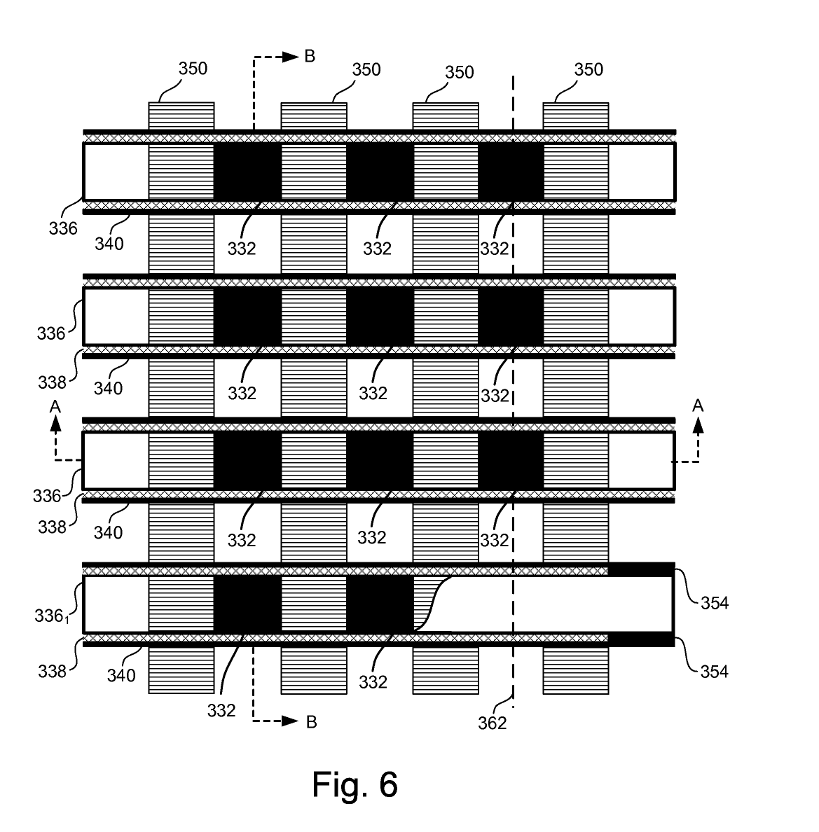

FIG. 6 is a plan view of a portion of an array of NAND flash memory cells in accordance with one embodiment. Parallel word lines 336 are shown horizontally, overlying and spanning a group of charge storage regions 332 to form the control gates for a row of memory cells. The word lines 336 are transparently illustrated to show the underlying charge storage regions 332, trench isolation regions 350, etc. It will be appreciated that the word lines are continuous and formed above trench isolation regions 350 and charge storage regions 332. Each charge storage region 332 is formed between adjacent trench isolation regions 350, shown vertically or in the bit line direction in FIG. 6. The horizontal or word line direction isolation provided by trenches 350 allows columns or strings of charge storage regions to be fabricated. Each column connects to an individual bit line 362 at one end (e.g., drain) and a common source line (not shown) at the other via contacts as shown in FIG. 1, thereby defining a NAND string or column of flash storage elements. Only one bit line 362 is illustrated (without contact connection) for ease of illustration. Typical memory arrays will include thousands of columns or NAND strings and can include any number of memory cells, not just four as illustrated.

In accordance with one embodiment, isolating members 340 are provided between charge storage regions 332 adjacent in the bit line direction. The isolating members reduce charge coupling between neighboring charge storage regions. An electrical field is associated with charge storage regions 332, dependent upon an amount of charge being stored in the region. These electrical fields can have components in any direction, thereby affecting the apparent threshold voltage of neighboring storage elements. Isolating members 340 can provide a termination point for these electrical fields to reduce the amount of charge coupling between neighboring charge storage regions, and thus, the occurrence of shifts in the apparent threshold voltage of memory cells. In one embodiment, isolating members 340 are isolating sidewalls or shield plates formed using sidewall fabrication techniques as hereinafter described.

While not so limited, shield plates 340 are particularly suited to reduce charge coupling between charge storage regions 340 adjacent to one another in the bit line direction. The shields provide termination for electrical fields having a component in the bit line direction as well as other directions. While plates 340 are provided between charge storage regions adjacent in the bit line direction, they can provide shielding between other neighboring charge storage regions, such as those on neighboring bit lines and word lines, and thus diagonally adjacent.

Shield plates 340 are formed between stacks adjacent in the bit line direction. Each plate is separated from its most adjacent charge storage region 332 by an insulating member 338. Insulating members 338 can be dielectric spacers formed along each stack to provide insulation between a corresponding shield plate and charge storage region in the bit line direction. Like shield plates 340, the spacers extend in the word line direction along the bit line sides of stacks adjacent in the bit line direction. In one embodiment, the insulating members are insulating sidewalls formed using sidewall fabrication techniques. Although not shown, insulating members 338 and isolating members 340 can also be formed along the bit line side of a charge storage region facing a select gate for the NAND string.

In one embodiment, shield plates 340 are floating and have no electrical connections. Formed of a conductive material such as polysilicon or metal, each floating shield plate is capacitively coupled to its most adjacent word line 336 by an insulation region 338. It's voltage will rise and fall with the voltage of its most adjacent control gate 336. The voltage will change in accordance with a ratio to which it is coupled to the control gate. That ratio is dependent upon the dielectric constant and size of the insulating region as well as the size and materials of the shield, charge storage region, and/or word line 336.

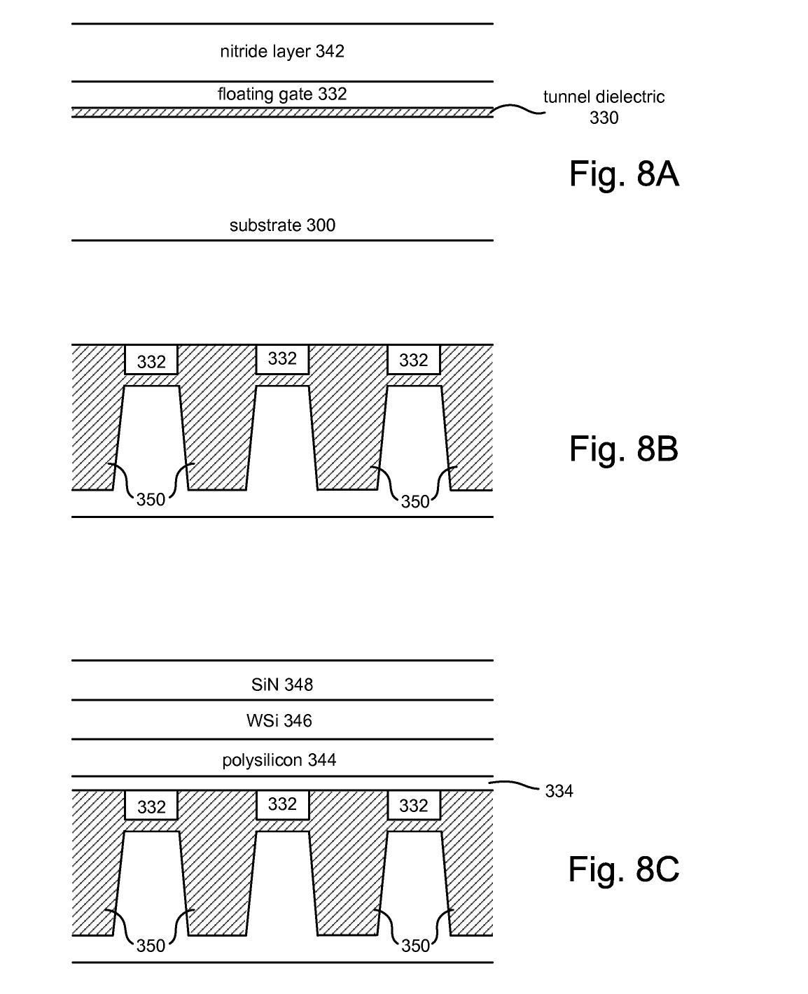

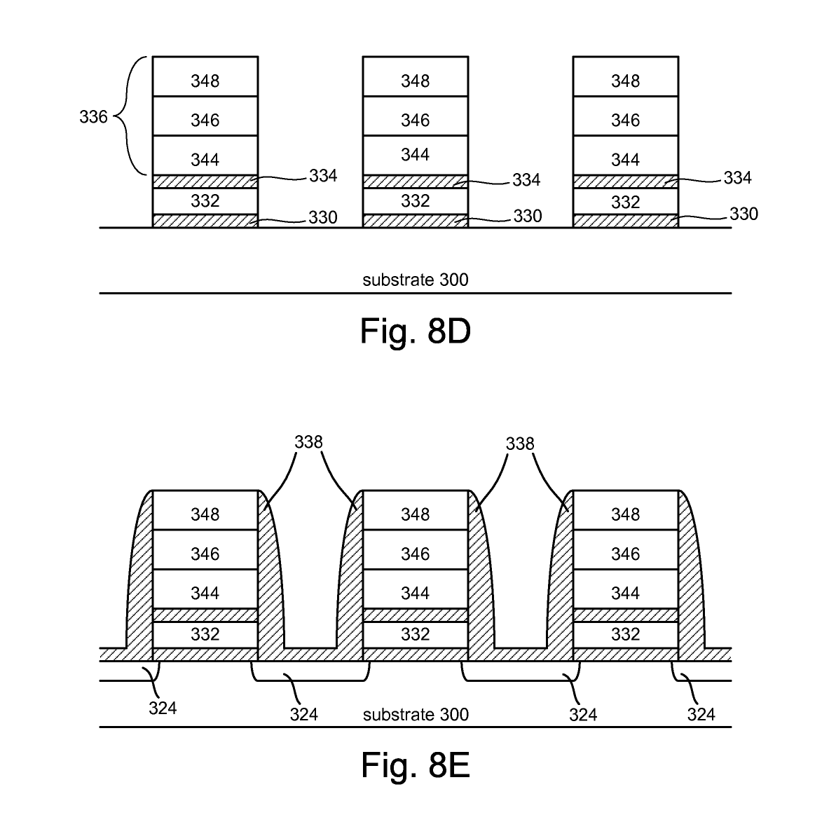

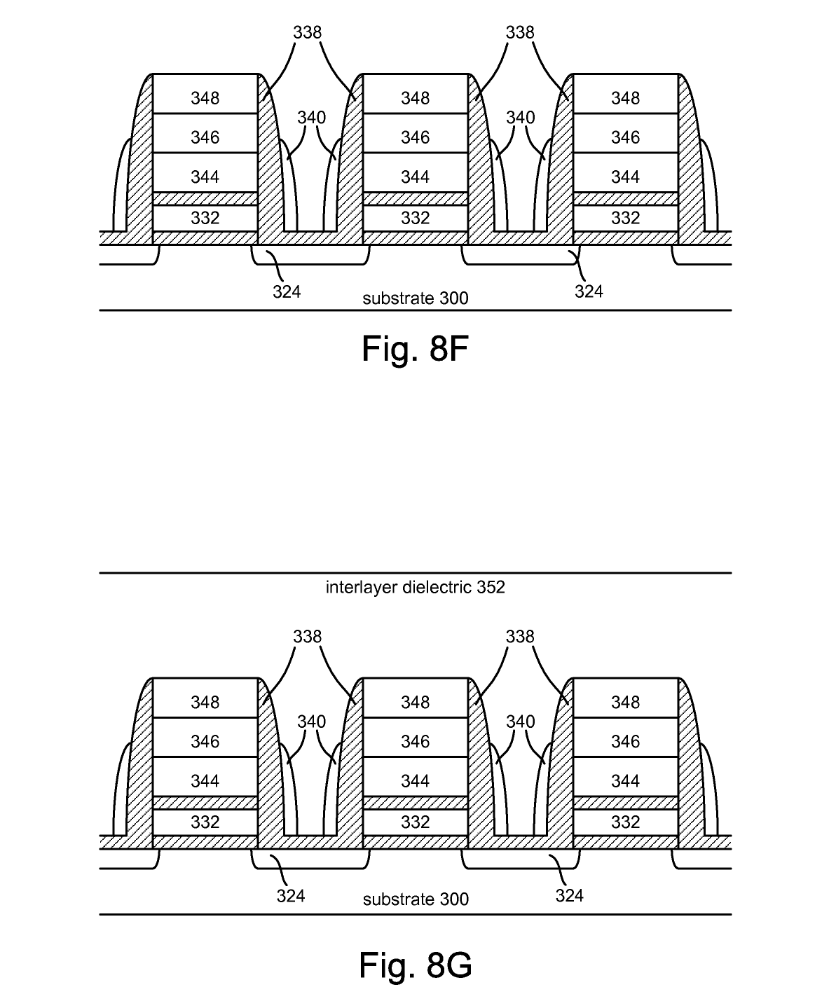

Techniques in accordance with embodiments of the present disclosure can simplify the fabrication of isolation members. In one embodiment, a floating shield plate 340 is formed by simply depositing the shield plate material and etching it back to form a plate like shield as illustrated with respect to FIGS. 8A-8G. In other embodiments, the plates are not floating, but connections are made to the word line away from the individual memory cells (e.g., before a first memory cell or after a last memory of a row) to avoid complex masking operations at the pitch size of the formed devices. For example, electrical connections can be provided before a first memory cell of a row, after a last memory cell of the row, or at an opening or break within the row of the memory array.

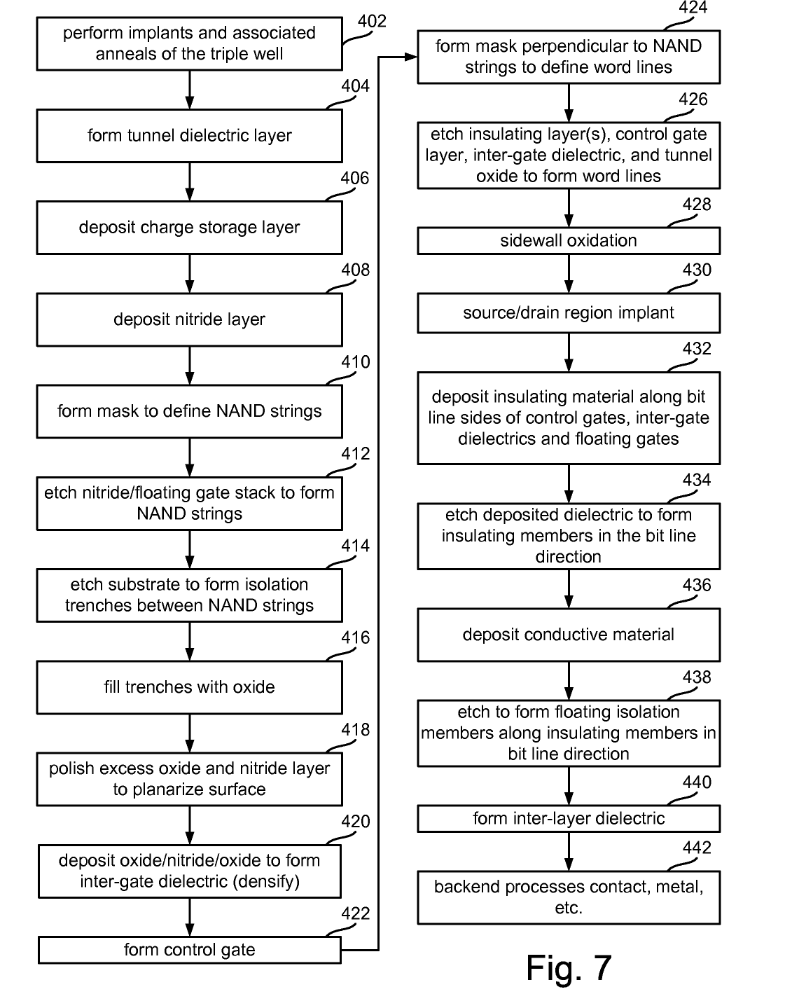

FIG. 7 is a flowchart depicting a method for forming a memory array in accordance with one embodiment. FIGS. 8A-8G illustrate a memory array at various points during a fabrication process such as that depicted in FIG. 7. Note that many steps of the fabrication process that will be understood by those skilled in the art are not illustrated for clarity of explanation. FIG. 7 is described with reference to FIGS. 8A-8G to highlight and illustrate select steps of the process but is not limited to the fabrication of such a device. Thus, while FIGS. 7 and 8A-8G depict a specific NAND flash memory example, the disclosed principles can be used in accordance with other fabrication processes to form other types of devices.

FIG. 8A is a cross-sectional view of the memory array along line A of FIG. 6, depicting a substrate 300 on and in which multiple nonvolatile NAND-type flash memory devices are to be fabricated. Substrate 300 is used generically to represent a substrate, but can also include P-wells and/or N-wells formed therein, as appropriate for various implementations. For example, a P-well and N-well may be formed in substrate 300 as depicted in FIG. 5.

At step 402 of FIG. 7, implanting and associated annealing of a triple well including substrate 300 is performed. After implanting and annealing the triple well, a dielectric layer 330 is formed above substrate 300. Dielectric 330 forms the tunnel dielectric region for many storage elements and can include an oxide or other suitable dielectric material in various embodiments. Dielectric layer 330 can be deposited using known chemical vapor deposition (CVD) processes, metal organic CVD processes, physical vapor deposition (PVD) processes, atomic layer deposition (ALD) processes, grown using a thermal oxidation process, or formed using another suitable process. In one embodiment, dielectric 330 is about 70-100 angstroms in thickness. However, thicker or thinner layers can be used in accordance with various embodiments. Additionally (and optionally), other materials may be deposited on, deposited under, or incorporated within the dielectric to form dielectric layer 330.

At step 406, a charge storage layer is deposited on top of the tunnel oxide layer. In FIG. 8A, the charge storage layer is first conductive layer 332 which will comprise the floating gates for the memory devices of the strings being fabricated. In one embodiment, conductive layer 332 is polysilicon deposited using known processes as described above. In other embodiments, other conductive materials can be used. In one embodiment, conductive layer 332 is about 500 angstroms in thickness. However, conductive layers thicker or thinner than 500 angstroms can be used in accordance with embodiments.

The charge storage layer deposited at step 406 can include conductive floating gate materials (e.g., polysilicon) or dielectric charge storage materials (e.g., silicon nitride). If an ONO triple layer dielectric is used, step 404 can include depositing the first silicon oxide layer and step 406 can include depositing the nitride charge storage layer. The second silicon oxide layer can be deposited in later steps to form the inter-gate dielectric (discussed hereinafter).

In one embodiment, a tailored dielectric layer is used and the charge storage regions formed therein. For example, a tailored layer of silicon rich silicon dioxide can be used to trap and store electrons. Such material is described in the following two articles, incorporated herein in their entirety by this reference: DiMaria et al., “Electrically-alterable read-only-memory using Si-rich S102 injectors and a floating polycrystalline silicon storage layer,” J. Appl. Phys. 52(7), July 1981, pp. 4825-4842; Hori et al., “A MOSFET with Si-implanted Gate-Si02 Insulator for Nonvolatile Memory Applications,” IEDM 92, April 1992, pp. 469-472. As an example, the thickness of the layer can be about 500 Angstroms. Steps 404 and 406 can be combined as the tailored dielectric layer will form the tunnel dielectric layer, charge storage layer, and optionally the inter-gate dielectric layer.

After depositing the floating gate or other charge storage layer, a nitride sacrificial layer 342 is deposited at step 408. The nitride layer can be about 400 angstroms in thickness. However the thickness can be more or less than the exemplary dimensions provided herein and may vary by implementation. Layers 330, 332, and 342 are preliminary NAND string stack layers used to form a plurality of devices. Multiple NAND strings will be constructed using these layers as starting layers.

After layers 330, 332, 342, have been formed, a hard mask can be deposited at step 410 over nitride layer 342 to begin defining the individual NAND strings of the device. Photolithography can be used to form strips of photoresist over the areas to become the NAND strings. After forming the strips of photoresist, the exposed mask layers can be etched, for example, using anisotropic plasma etching (reactive ion etching with proper balance between physical and chemical etching for each planar layer encountered). With the mask etched, the photoresist can be removed.

At step 412, the nitride layer and floating gate layer are etched using the mask to form individual NAND string stack regions. These will become individual NAND strings for the memory device. The three NAND string stack regions are adjacent to one another in the word line direction. At step 414, substrate 300 is etched to form isolation trenches 350 between the stacks. The trenches isolate adjacent columns of memory cells and their corresponding active regions of the substrate from each other to define individual NAND strings. The isolation trenches 350 are filled with a dielectric such as silicon dioxide at step 416 to provide effective isolation. The excess oxide and any remaining portion of nitride layer 342 are polished at step 418, using chemical mechanical polishing for example, to planarize the upper surfaces of each floating gate 332. FIG. 8B is a cross-sectional view of the memory array along line A of FIG. 6 after step 418.

Various techniques for forming isolation trenches 350 can be used in accordance with embodiments. For example, trenches 350 can be deep self-aligned trenches formed by etching through pre-deposited floating gate and tunnel dielectric layers as has been described. The trenches can be filled with a grown dielectric in one embodiment such that subsequently deposited control gate layers can extend between floating gates in the word line direction for increased coupling. For more information on one technique utilizing deep self-aligned trenches, see U.S. patent application Ser. No. 10/996,030, entitled “SELF-ALIGNED TRENCH FILLING WITH HIGH COUPLING RATIO,” by Jack H. Yuan, filed Nov. 23, 2004, incorporated by reference herein in its entirety. In one embodiment, trenches 350 each include a lower trench portion filled with a grown dielectric and an upper trench portion filled with a deposited dielectric, as described in U.S. patent application Ser. No. 11/251,386, entitled “SELF-ALIGNED TRENCH FILLING FOR NARROW GAP ISOLOATION REGIONS,” by Jack H. Yuan, filed Oct. 14, 2005, incorporated by reference herein in its entirety. Other techniques such as LOCOS or SWAMI as previously described can be used in other embodiments. In some embodiments, the isolation trenches may be formed prior to the floating gates and/or tunnel dielectric as is presently described.

A dielectric is deposited at step 420 for the inter-gate dielectric region 334. In one embodiment, the inter-gate dielectric is multi-layered ONO (oxide-nitride-oxide) having a first oxide layer thickness of 50 angstroms, a nitride layer thickness of 70 angstroms, and a second oxide layer thickness of 70 angstroms. The effective ONO thickness of such a configuration is around 140 angstroms. Other sizes and types of materials can be used. One or more layers for control gates 336 are formed at step 422. In one embodiment, control gates 336 have a thickness of about 2000 angstroms. In one embodiment, a poly-silicon layer 344, Tungsten Silicide (WSi) layer 346, and Silicon Nitride (SiN) 348 are deposited to form control gates 336. WSi 346 is a lower resistance layer and SiN is an insulator. FIG. 8C depicts a cross-sectional view of the memory array alone line A of FIG. 6 after step 422.

At step 424, patterns of photoresist are formed over a hard mask such as deposited oxide above SiN 348 to define the individual control gates or word lines 336 for the array. Layers 348, 346, 344, 334, 332, and 330 are etched at step 426 to form word lines in a direction substantially perpendicular (horizontal in FIGS. 8A-8C) to the bit line direction (vertical in FIGS. 8A-8C). Plasma etching, ion milling, purely physical ion etching, or another suitable technique can be used at step 426 to form the word lines. In one embodiment, tunnel dielectric layer 330 is not etched at step 426, leaving continuous strips of dielectric material above the substrate in the bit line direction, directly below each charge storage region as well as therebetween. FIG. 8D is a cross-sectional view of the memory array along line B of FIG. 6, illustrating a cut of the array with three stacks adjacent to one another in the bit line direction, depicted horizontally in FIG. 8D.

At step 428, sidewall oxidation, sidewall deposition, or a combination of both is performed. The device can be placed in a furnace at a high temperate with some fraction percentage of ambient oxygen gas, so that the exposed surfaces oxidize, which provides a layer of protection. Sidewall oxidation can also be used to round the edges of the floating gate and the control gate. An alternative to high temperature (e.g. over 1000 degrees Celsius) oxide growth is low temperature (e.g. 400 degrees Celsius) oxide growth in high density Krypton plasma. More information about sidewall oxidation can be found in “New Paradigm of Silicon Technology,” Ohmi, Kotani, Hirayama and Morimoto, Proceedings of the IEEE, Vol. 89, No. 3, March 2001; “Low-Temperature Growth of High Silicon Oxide Films by Oxygen Radical Generated in High Density Krypton Plasma,” Hirayama, Sekine, Saito and Ohmi, Dept. of Electronic Engineering, Tohoku University, Japan, 1999 IEEE; and “Highly Reliable Ultra thin Silicon Oxide Film Formation at Low Temperature by Oxygen Radical Generated in High-Density Krypton Plasma,” Sekine, Saito, Hirayama and Ohmi, Tohoku University, Japan, 2001 IEEE; all three of which are incorporated herein by reference in their entirety.

The N+ source/drain regions 324 are formed at step 430 in an implant process. For example, arsenic or phosphorous implantation can be used. Halo implantation can be used and in some embodiments, an anneal process is performed. FIG. 8E depicts a cross-sectional view of the memory array along line B of FIG. 6 after forming N+ regions 324 between active areas in the substrate below adjacent charge storage regions 332.

Insulating members 338 are formed at steps 432 and 434 between stacks adjacent to one another in the bit line direction. Each layer of the stack has an upper and lower surface, two substantially parallel sides in the word line direction, and two substantially parallel sides in the bit line direction (a first bit line side is depicted in FIGS. 8A-8C). The insulating members are formed along the bit line sides of adjacent charge storage regions 332, inter-gate dielectric regions 334, and the multiple layers of control gate 336, as depicted in FIG. 8E. In one embodiment, the insulating members are only formed along the conductive portions of control gate 336 (e.g., polysilicon 344) and not layers such as WSi 346 or SiN 348. The insulating members 338 are dielectric sidewall spacers in one embodiment (e.g. oxide, nitride, etc.). They can be formed by depositing an oxide using ALD, CVD, etc. (step 432) and etching it back (step 434) to form insulating sidewalls.

A conductive material is formed for the isolating members 340 at step 436 such as by depositing polysilicon, metal or other material. Polysilicon is highly conformal and in one embodiment is deposited to form isolating shield plates 340. The deposited material can be etched at step 438 to form sidewall plates along each insulating sidewall 338. In one embodiment, shield plates 340 have a thickness in the bit line direction of about 50 angstroms or less. Other thicknesses greater or less than 50 angstroms can be used. For example, a 20 or 10 angstrom shield plate can be used in one embodiment. Sufficient termination can be provided with a very thin conductive layer of this magnitude. FIG. 8F depicts a cross-sectional view of the memory array along line B of FIG. 6 with shield plates 340 formed along the insulating regions 338. Two plates are provided between adjacent charge storage regions in the bit line direction (between opposing bit line sides of adjacent floating gates). Each shield plate can provide termination for electrical fields resulting from charges stored on or in the adjacent charge storage regions. Shifts in the apparent threshold voltage of the memory cells can thus be decreased.

The inter-layer dielectric 352 is formed at step 440 to fill in the array. FIG. 8G is a cross-sectional view of the memory array along line B of FIG. 6 after step 440. At step 442, various backend processes can be performed. For example, various contacts can be etched, metal interconnects formed, etc. to complete fabrication of the array.

Various modifications to shield plates 340 can be made in accordance with embodiments. FIGS. 8F-8G depict shield plates formed between stacks in the bit line direction and extending in the word line direction. The plates are formed from about the level of the lower surface of the charge storage region to about the middle of WSi layer 346. The shields may not extend all the way to the lower surface of charge storage regions 332 in one embodiment. In another embodiment, the shield plates are formed almost to the upper portion of substrate 300. The shield plates can also extend to about the level of the upper surface of SiN layer 348 or only to the upper surface of charge storage region 332. In one embodiment, insulating members 338 do not extend to the level of layers such as WSi 346 or SiN 348 that form part of the control gates. In each case, the floating shield plate is electrically insulated from the control gates 336 (344-348).

Because the shield plates are floating and made of conductive material, they will be capacitively coupled to their most adjacent floating gates and control gates. This can increase the influence of a control gate 336 over its corresponding charge storage region. The control gate will be capacitively coupled to the shield plate and the shield plate will be capacitively coupled to the charge storage region. Therefore, control gates will exhibit stronger influence over the charge storage regions.

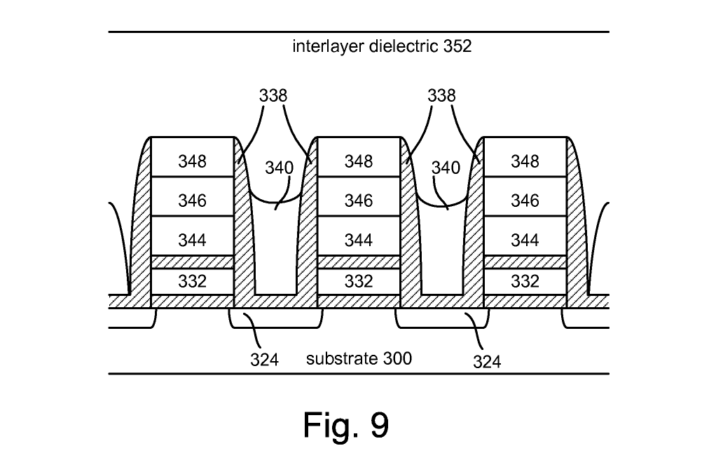

FIG. 9 depicts an alternate embodiment where a single floating shield plate 340 is included between adjacent charge storage regions 332. A single plate between adjacent word line stacks still provides a termination point for electrical fields resulting from charge stored in the adjacent storage regions. The single shield plate 340 will be capacitively coupled to each of its most adjacent stacks. It will not track as closely the voltage of an adjacent word line when compared with the two plates as shown in FIGS. 8F and 8G. However, such an arrangement can still provide shielding between adjacent charge storage regions. Because a single shield plate is provided between two control gates and charge storage regions, the plate is not electrically connected to either of the adjacent word lines in one embodiment. In this manner, the shield plate provides independent electrical isolation for both of the adjacent charge storage regions.

A single shield plate as illustrated in FIG. 9 is particularly suitable for implementations with decreased device dimensions. When the memory cells of the array are scaled, the distance between adjacent stack regions in the bit line direction decreases. To form two isolation shield plates as illustrated in FIGS. 8F and 8G with independent electrical characteristics, the deposition or other process must form the two plates and provide adequate isolation between them. If a single plate is formed as illustrated in FIG. 9, the fabrication requirements at this level of the process can be relaxed. Steps 436 and 438 (FIG. 7) need only deposit a conductive layer and etch it to form a single shield plate 340. Accordingly, the requirements of depositing and etching within the narrow space between adjacent stack regions are less.

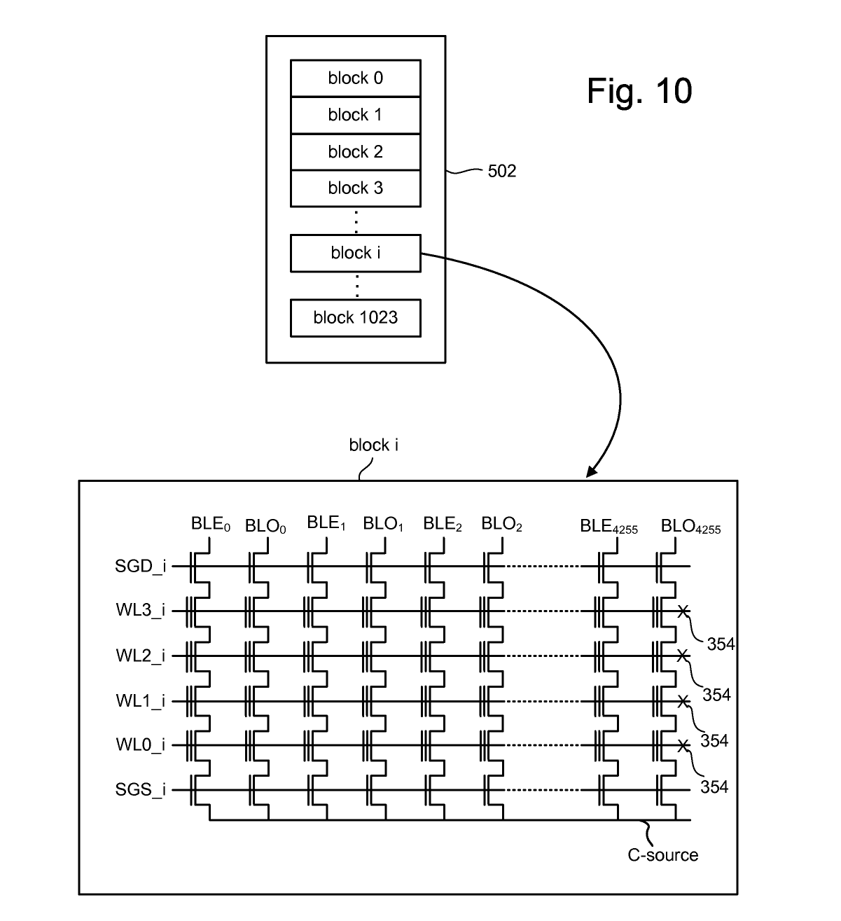

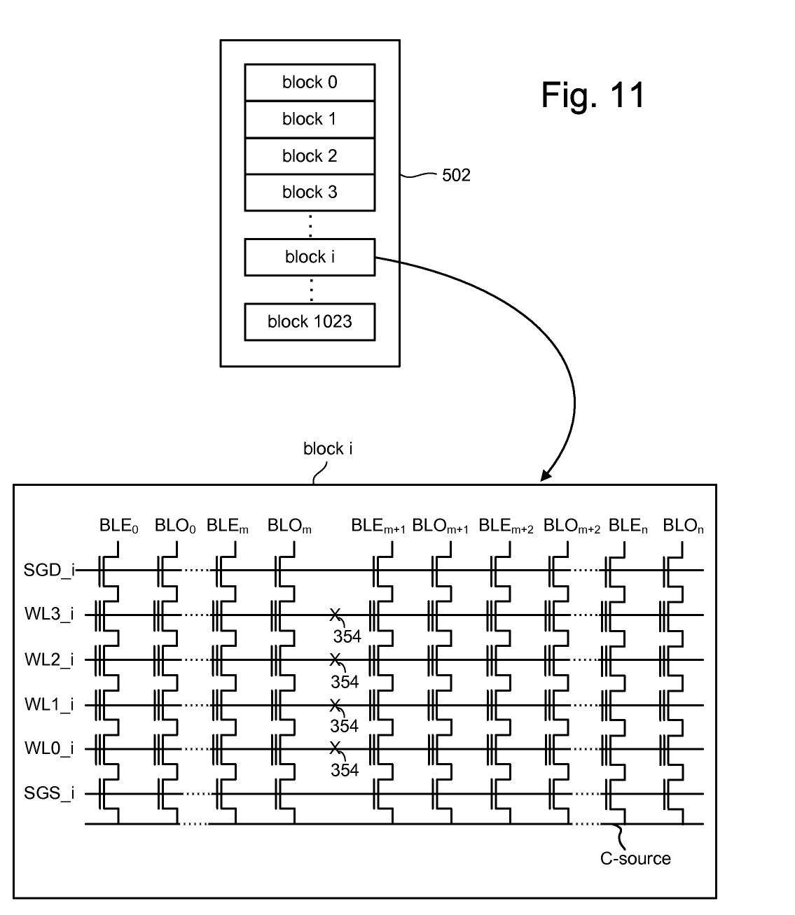

In embodiments that utilize two shield plates between adjacent charge storage regions, the shield plates can be electrically connected to their most adjacent word line 336. Referring to FIG. 6 for example, the right portion of word line 336, is depicted in its normal arrangement, with one or more layers overlying and thus obstructing inter-gate dielectric region 334, floating gates 332, and trenches 350 from view. Contacts 354 are provided at the end of world line 336, between the word line and its two most adjacent shield plates 340. The contacts can be etched contacts or simple metal interconnects formed at step 442 of FIG. 7 as part of the back end processes. Because the connections are not formed along the entire length of each word line, including where each control gate overlies a corresponding floating gate, precise alignment at the device pitch is not necessary. The connections can be provided at portions of the memory array away from any of the individual memory cells. With a direct electrical connection, the shield plates will be at the same potential as the word line, and provide termination and increased coupling as already described. The locations of electrical connections 354 are more fully described with respect to FIGS. 10 and 11.

FIG. 10 depicts an exemplary structure of memory cell array 502. As one example, a NAND flash EEPROM is described that is partitioned into 1,024 blocks. The data stored in each block can be simultaneously erased. In one embodiment, the block is the minimum unit of cells that are simultaneously erased. In each block, in this example, there are 8,512 columns that are divided into even columns and odd columns. The bit lines are also divided into even bit lines (BLE) and odd bit lines (BLO). FIG. 10 shows four memory cells connected in series to form a NAND string. Although four cells are shown to be included in each NAND string, more or less than four can be used (e.g., 16, 32, or another number). One terminal of the NAND string is connected to a corresponding bit line via a first select transistor (also referred to as a select gate) SGD, and another terminal is connected to c-source via a second select transistor SGS. In one embodiment, a contact or electrical connection 354 is provided between a word line and one or more shield plates for the corresponding row of memory cells. As depicted, the connection is provided at a portion of the word line outside or beyond the individual memory cells of the block. For example, FIG. 10 shows a contact 354 beyond the last memory cell of each row of memory cells. A simple contact, via, or other interconnect can be formed between the word line and shield plate. In another embodiment, contact 354 can be formed outside of the block of memory cells at a location beyond the first memory cell of a row. For example, a contact could be formed between word line WL3_i and its corresponding shield plate(s) at a portion of WL3_i before the memory cell of the row connected to BLE₀. This connection can be at a portion of the word line after row control circuitry 506 and before the first memory cell (connected to BLE₀).

It is common in many array implementations to provide a periodic break in the memory array after a specified number of bit lines. For example, after every 100 bit lines a portion of the array may be open and not include any memory cells before another 100 bit lines are formed. These individual portions of the memory array may be referred to as a sub-array.

FIG. 11 depicts an array and a detailed view of a block when such a configuration is utilized. The illustrated block includes individual portions that are part of different sub-arrays. The sub-arrays include a number m of odd and even bit lines. Thus, the illustrated block includes a first portion that is formed of bit lines BLE₀, BLO₀ through bit lines BLEₘ, BLOₘ. The number m of bit lines before each opening in the array may vary by embodiment. For example, m may be equal to 50 or 100, or several hundreds of bit lines in various implementations. The block in FIG. 11 has been simplified to only show one such break in the array but periodic breaks in the array after every m odd and even bit lines can be provided until the end of the array is reached. Connections 354 between the shield plates and adjacent word lines can be provided at each opening or break in the array or at only a portion of the openings.

The periodic opening in the memory array is especially suitable for formation of contacts between the isolating members and their corresponding word line. FIG. 11 illustrates a contact 354 between the isolating members and corresponding word line at the opening between BLOₘ and BLEₘ₊₁. Because the opening in the array is large, the level of precision required to form the contact between an isolating member and word line is not as great as would be required were continuous contact along the length of the word line attempted. The contact need not be formed at the device level pitch. If the device pitch is 50 nm, for example, the contact may be formed with a larger size of 100 nm or more for example. This can greatly improve the ease of fabricating the isolating members and improve yields. Less failures attributable to inadvertent shorts or opens can be expected as the level of precision required in fabrication is less. Although not illustrated, contacts between isolating members and a corresponding word line can be made at every opening (or some portion thereof) in the memory array in one embodiment. Thus, after another m odd and even bit lines, additional contacts 354 can be formed between the isolating members and word lines.

During read and programming operations for memory cells of one embodiment, 4,256 memory cells are simultaneously selected. The memory cells selected have the same word line (e.g. WL2-i), and the same kind of bit line (e.g. even bit lines). Therefore, 532 bytes of data can be read or programmed simultaneously. These 532 bytes of data that are simultaneously read or programmed form a logical page. Therefore, in this example, one block can store at least eight pages. When each memory cell stores two bits of data (e.g. a multi-level cell), one block stores 16 pages.

In the read and verify operations, the select gates (SGD and SGS) of a selected block are raised to one or more select voltages and the unselected word lines (e.g., WL0, WL1 and WL3) of the selected block are raised to a read pass voltage (e.g. 4.5 volts) to make the transistors operate as pass gates. The selected word line of the selected block (e.g., WL2) is connected to a reference voltage, a level of which is specified for each read and verify operation in order to determine whether a threshold voltage of the concerned memory cell is above or below such level. For example, in a read operation of a one bit memory cell, the selected word line WL2 is grounded, so that it is detected whether the threshold voltage is higher than 0V. In a verify operation of a one bit memory cell, the selected word line WL2 is connected to 2.4V, for example, so that as programming progresses it is verified whether or not the threshold voltage has reached 2.4V. The source and p-well are at zero volts during read and verify. The selected bit lines (BLe) are pre-charged to a level of, for example, 0.7V. If the threshold voltage is higher than the read or verify level, the potential level of the concerned bit line (BLe) maintains the high level, because of the associated non-conductive memory cell. On the other hand, if the threshold voltage is lower than the read or verify level, the potential level of the concerned bit line (BLe) decreases to a low level, for example less than 0.5V, because of the conductive memory cell. The state of the memory cell is detected by a sense amplifier that is connected to the bit line and senses the resulting bit line voltage. The difference between whether the memory cell is programmed or erased depends on whether or not net negative charge is stored in the floating gate. For example, if negative charge is stored in the floating gate, the threshold voltage becomes higher and the transistor can be in enhancement mode of operation.

When programming a memory cell in one example, the drain and the p-well receive 0 volts while the control gate receives a series of programming pulses with increasing magnitudes. In one embodiment, the magnitudes of the pulses in the series range from 7 volts to 20 volts. In other embodiments, the range of pulses in the series can be different, for example, having a starting level of higher than 7 volts. During programming of memory cells, verify operations are carried out in the periods between the programming pulses. That is, the programming level of each cell of a group of cells being programmed in parallel is read between each programming pulse to determine whether or not it has reached or exceeded a verify level to which it is being programmed. One means of verifying the programming is to test conduction at a specific compare point. The cells that are verified to be sufficiently programmed are locked out, for example in NAND cells, by raising the bit line voltage from 0 to Vdd (e.g., 2.5 volts) for all subsequent programming pulses to terminate the programming process for those cells. In some cases, the number of pulses will be limited (e.g. 20 pulses) and if a given memory cell is not sufficiently programmed by the last pulse, an error is assumed. In some implementations, memory cells are erased (in blocks or other units) prior to programming.

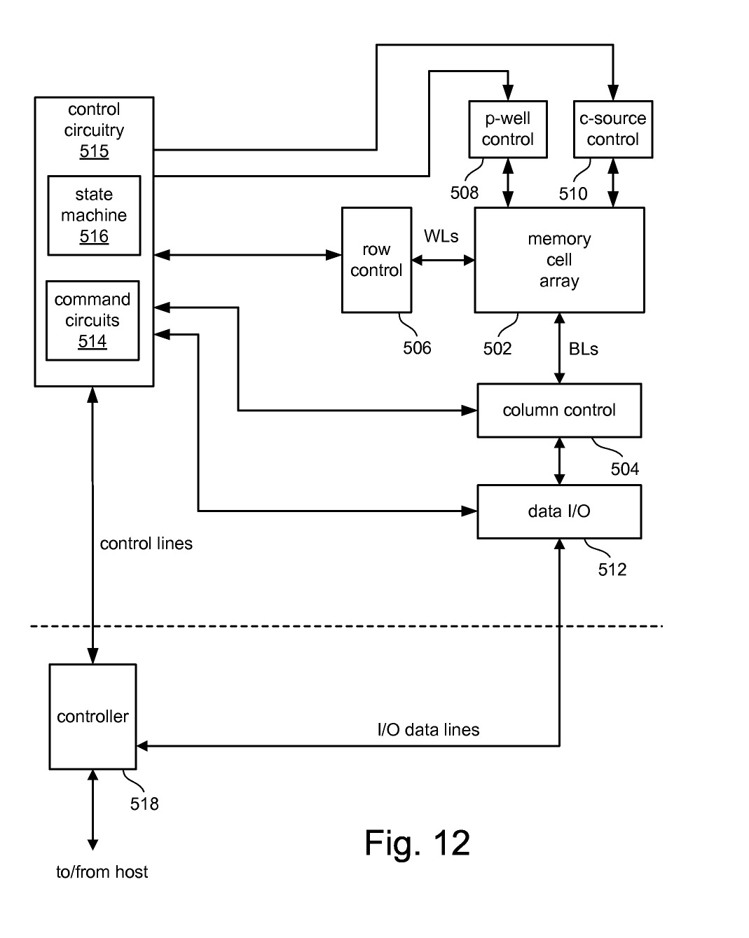

FIG. 12 is a block diagram of one embodiment of a flash memory system that can be used to implement one or more embodiments of the present disclosure. Other systems and implementations can be used. Memory cell array 502 is controlled by column control circuit 504, row control circuit 506, c-source control circuit 510 and p-well control circuit 508. Column control circuit 504 is connected to the bit lines of memory cell array 502 for reading data stored in the memory cells, for determining a state of the memory cells during a program operation, and for controlling potential levels of the bit lines to promote or inhibit programming and erasing. Row control circuit 506 is connected to the word lines to select one of the word lines, to apply read voltages, to apply program voltages combined with the bit line potential levels controlled by column control circuit 504, and to apply an erase voltage. C-source control circuit 510 controls a common source line (labeled as “C-source” in FIG. 9) connected to the memory cells. P-well control circuit 508 controls the p-well voltage.

The data stored in the memory cells are read out by the column control circuit 504 and are output to external I/O lines via data input/output buffer 512. Program data to be stored in the memory cells are input to the data input/output buffer 512 via the external I/O lines, and transferred to the column control circuit 504. The external I/O lines are connected to controller 518.

Command data for controlling the flash memory device is input to controller 518. The command data informs the flash memory of what operation is requested. The input command is transferred to state machine 516 which is part of control circuitry 515. State machine 516 controls column control circuit 504, row control circuit 506, c-source control 510, p-well control circuit 508 and data input/output buffer 512. State machine 516 can also output status data of the flash memory such as READY/BUSY or PASS/FAIL.

Controller 518 is connected to or connectable with a host system such as a personal computer, a digital camera, or personal digital assistant, etc. It communicates with the host that initiates commands, such as to store or read data to or from the memory array 502, and provides or receives such data. Controller 518 converts such commands into command signals that can be interpreted and executed by command circuits 514 which are part of control circuitry 515. Command circuits 514 are in communication with state machine 516. Controller 518 typically contains buffer memory for the user data being written to or read from the memory array.

One exemplary memory system comprises one integrated circuit that includes controller 518, and one or more integrated circuit chips that each contain a memory array and associated control, input/output and state machine circuits. There is a trend to integrate the memory arrays and controller circuits of a system together on one or more integrated circuit chips. The memory system may be embedded as part of the host system, or may be included in a memory card (or other package) that is removably inserted into the host systems. Such a card may include the entire memory system (e.g. including the controller) or just the memory array(s) with associated peripheral circuits (with the controller or control function being embedded in the host). Thus, the controller can be embedded in the host or included within the removable memory system.

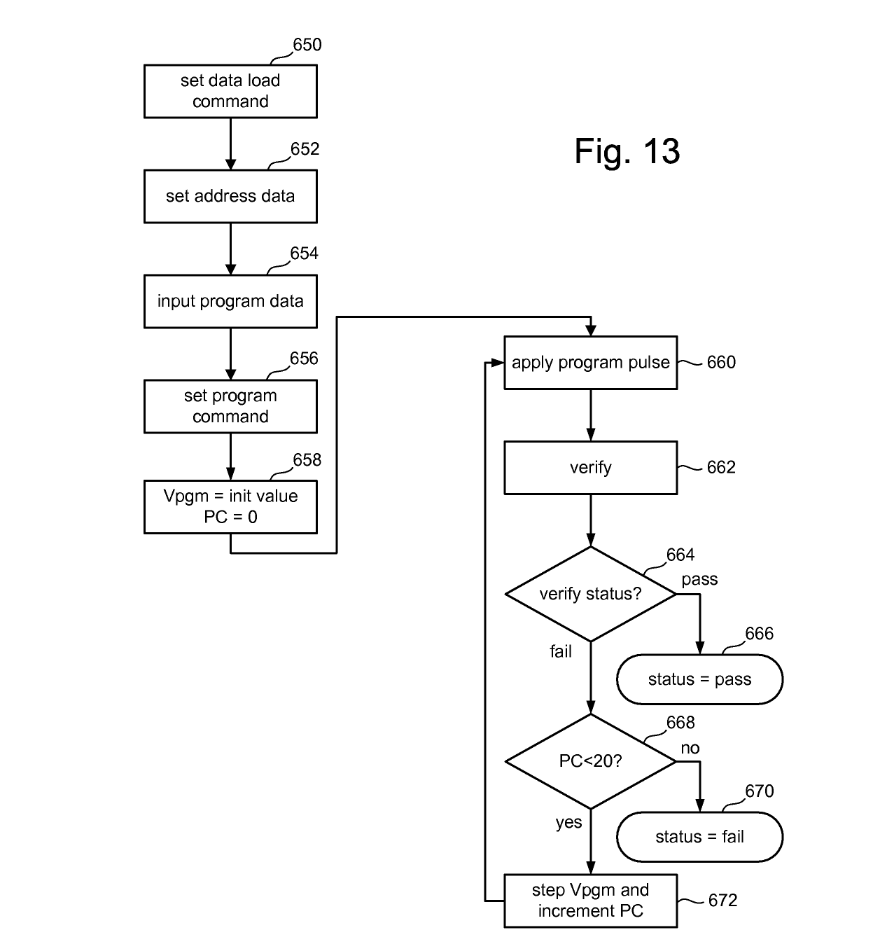

FIG. 13 is a flowchart describing a method for programming a nonvolatile memory system. As will be apparent to those of ordinary skill in the art, various steps can be modified, added, or removed depending on a specific application or implementation while still remaining within the scope and spirit of the present disclosure. In various implementations, memory cells are erased (in blocks or other units) prior to programming. At step 650 of FIG. 13, a data load command is issued by controller 518 and input to command circuit 514, allowing data to be input to data input/output buffer 512. The input data is recognized as a command and latched by state machine 516 via a command latch signal, not illustrated, input to command circuits 514. In step 652, address data designating the page address is input to row controller 506 from controller 518. The input data is recognized as the page address and latched via state machine 516, effected by the address latch signal input to command circuits 514. At step 654, 532 bytes of program data are input to data input/output buffer 512. It should be noted that 532 bytes of program data are specific to the particular implementation described, and other implementations will require or utilize various other sizes of program data. That data can be latched in a register for the selected bit lines. In some embodiments, the data is also latched in a second register for the selected bit lines to be used for verify operations. At step 656, a program command is issued by controller 318 and input to data input/output buffer 512. The command is latched by state machine 316 via the command latch signal input to command circuits 514

At step 658, Vpgm, the programming pulse voltage level applied to the selected word line, is initialized to the starting pulse (e.g. 12 volts), and a program counter PC maintained by state machine 516, is initialized at 0. At step 660, a program voltage (Vpgm) pulse is applied to the selected word line. The bit lines that include a memory cell to be programmed are grounded to enable programming, while the other bit lines are connected to Vdd to inhibit programming during application of the programming pulse.

At step 662, the states of the selected memory cells are verified. If it is detected that the target threshold voltage of a selected cell has reached the appropriate level (for example, the programmed level for logic 0 or a particular state of a multi-state cell), then the selected cell is verified as programmed to its target state. If it is detected that the threshold voltage has not reached the appropriate level, the selected cell is not verified as programmed to its target state. Those cells verified as programmed to their target state at step 362 will be excluded from further programming. At step 664, it is determined whether all cells to be programmed have been verified to have programmed to their corresponding states, such as by checking an appropriate data storage register designed to detect and signal such a status. If so, the programming process is complete and successful because all selected memory cells were programmed and verified to their target states. A status of pass is reported in step 666. If at step 664, it is determined that not all of the memory cells have been so verified, then the programming process continues. At step 668, the program counter PC is checked against a program limit value. One example of a program limit value is 20. If the program counter PC is not less than 20, then the program process is flagged as failed and a status of fail is reported at step 670. If the program counter PC is less than 20, then the Vpgm level is increased by the step size and the program counter PC is incremented at step 672. After step 672, the process loops back to step 660 to apply the next Vpgm program pulse. At the end of a successful program process, the threshold voltages of the memory cells should be within one or more distributions of threshold voltages for programmed memory cells or within a distribution of threshold voltages for erased memory cells.

The flowchart of FIG. 13 depicts a single-pass programming method as can be applied for binary storage. In a two-pass programming method as can be applied for multi-level storage, for example, multiple programming or verification steps may be used in a single iteration of the flowchart. Steps 650-677 may be performed for each pass of the programming operation. In a first pass, one or more program pulses may be applied and the results thereof verified to determine if a cell is in the appropriate intermediate state. In a second pass, one or more program pulses may be applied and the results thereof verified to determine if the cell is in the appropriate final state.

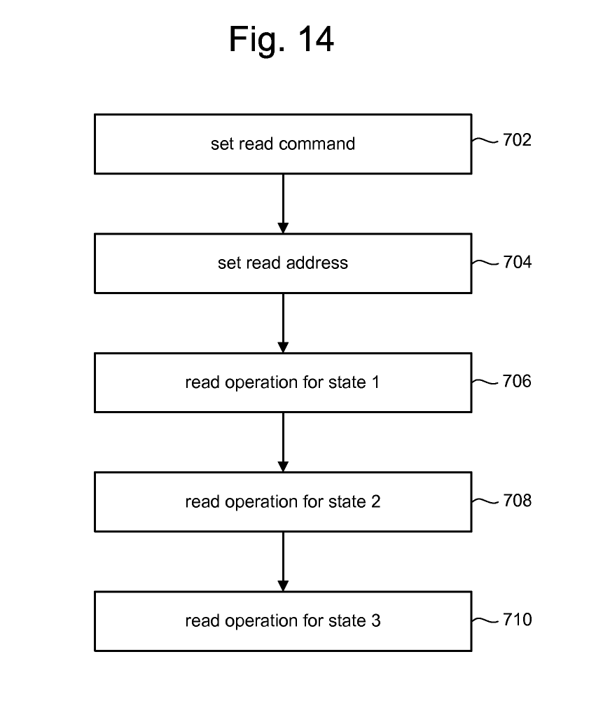

FIG. 14 is a flow chart describing one embodiment of a process for reading a memory cell in array 502. In step 702, a read command is received from the host and stored in the state machine. In step 704, an address is received and stored. The process of FIG. 14 assumes a four state memory cell, with an erased state and three programmed states. Therefore, in one embodiment, three read operations are performed in order to read the data stored in the memory cell. If the memory has eight states, then seven read operations are performed; if the memory has sixteen states, then fifteen read operations are performed, etc. In step 706, the first read operation is performed. A first read compare point, equivalent to a threshold voltage between state 0 and state 1 is applied to the selected word line, and the sense amplifier on each bit line makes a binary decision as to whether the cell at the intersection of the selected word line and the corresponding bit line is on or off. If the cell is detected to be on, then it is read as being in state 0, otherwise the cell is in state 1, 2 or 3. In other words, if the threshold voltage of the memory cell is greater than the first read compare point, the memory cell is assumed to be in the erased state 0.

In step 708, the second read operation is performed. A second read compare point, equivalent to a threshold voltage between state 2 and state 1 is applied to the selected word line, and the sense amplifier on each bit line makes a binary decision as to whether the cell at the intersection of the selected word line and the corresponding bit line is on or off. An “off” bit line indicate that the corresponding memory cell is either in state 0 or in state 1. An “on” bit line indicates that the corresponding memory cell is in either state 2 or state 3.

In step 710, the third read operation is performed. A third read compare point, equivalent to a threshold voltage between state 3 and state 2 is applied to the selected word line, and the sense amplifier on each bit line makes a binary decision as to whether the cell at the intersection of the selected word line and the corresponding bit line is on or off. An “off” bit line will indicate that the corresponding cell is either in state 0, in state 1, or in state 2. An “on” bit line will indicate that the corresponding memory cell is in state 3. The information obtained during the three sequential steps explained above is stored in latches. A decoder is used to combine the results of the three read operations in order to find the state of each cell. For example, state 1 would be a result of the following three read results: on in step 706, off in step 708, and off in step 710. The above sequence of the read operations can be reversed, corresponding to the verify waveform sequence depicted in FIG. 5. Note that other read processes can also be used with the present invention.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

I claim:

1. A method of fabricating nonvolatile memory, comprising:
forming a plurality of adjacent charge storage regions in a first direction along a substrate, said charge storage regions having a lower surface level;
forming a plurality of adjacent control gates above said charge storage regions, said control gates having an upper surface level;
forming insulating members along sides of said charge storage regions facing adjacent charge storage regions in said first direction and along sides of said control gates facing adjacent control gates in said first direction, said insulating members extending from at least said lower surface level of said floating gates to at least said upper surface level of said control gates; and
forming conductive isolating members along said insulating members, said isolating members insulated from said charge storage regions and said control gates by said insulating members.

2. The method of claim 1, wherein said conductive isolating members are floating.

3. The method of claim 1, wherein:
each charge storage region of said plurality is part of an individual row of charge storage regions extending in a second direction substantially perpendicular to said first direction;
each isolating member extends along and provides shielding for a row of charge storage regions to which it is closest in said first direction;
said forming a plurality of adjacent control gates includes forming a plurality of world lines extending in said second direction, wherein each word line is formed above a corresponding row of charge storage regions extending in said second direction; and
said method further comprises providing an electrical connection between each isolating member and a word line formed above said row of charge storage regions to which said each isolating member is closest in said first direction.

4. The method of claim 3, wherein:
each word line is formed from a corresponding row of control gates in said second direction.

5. The method of claim 3, wherein:
forming a plurality of word lines includes forming each word line above a corresponding row of control gates in said second direction and providing an electrical connection between said each word line and its corresponding row of control gates.

6. The method of claim 3, wherein:
said electrical connection is provided at a portion of said word line between row control circuitry for said word line and a first charge storage region of said corresponding row of charge storage regions for said word line.

7. The method of claim 3, wherein:
said electrical connection is provided at a portion of said word line that extends beyond a last charge storage region of said corresponding row of charge storage regions for said word line, said last charge storage region is a charge storage region farthest from row control circuitry for said word line

8. The method of claim 3, wherein:
said nonvolatile memory includes a first plurality of bit lines having substantially equally spacing therebetween and a second plurality of bit lines having substantially equal spacing therebetween;
a last bit line of said first plurality of bit lines is adjacent to a first bit line of said second plurality of bit lines, said last bit line and said first bit line have a larger spacing therebetween than said substantially equal spacing between bit lines of said first plurality and bit lines of said second plurality; and
said electrical connection is provided at said larger spacing between said last bit line of said first plurality and said first bit line of said second plurality.

9. The method of claim 1, wherein said isolating members shield said adjacent charge storage regions from electrical field coupling based on charge stored in said adjacent charge storage regions.

10. The method of claim 9, wherein said isolating members shield said adjacent charge storage regions to reduce shifts in the apparent threshold voltages of storage elements formed from said charge storage regions and control gates.

11. The method of claim 1, wherein each conductive isolating member is capacitively coupled to its most adjacent charge storage region and control gate, thereby increasing a coupling ratio between said adjacent charge storage region and said adjacent control gate.

12. The method of claim 1, wherein:
said first direction corresponds to a bit line axis for a NAND string of flash memory devices formed from said plurality of charge storage regions and said plurality of control gates;
said forming insulating members comprises, for each pair of charge storage regions and control gates adjacent in said first direction, forming a first insulating member along a first bit line side of a first charge storage region of said pair and a first bit line side of a first control gate of said pair, and forming a second insulating member along a first bit line side of a second charge storage region of said pair and a first bit line side of a second control gate of said pair; and
said forming conductive isolating members comprises, for said each pair, forming a first isolating member along said first insulating member and a second isolating member along said second insulating member.

13. The method of claim 1, wherein:
said plurality of adjacent charge storage regions includes a first charge storage region adjacent a first select gate for said plurality and a last charge storage region adjacent a second select gate for said plurality;
said forming insulating members includes forming an insulating member along a side of said first charge storage region adjacent to said first select gate in said first direction and forming an insulating member along a side of said last charge storage region adjacent to said second select gate in said first direction; and
said forming conductive isolating members includes forming a first isolating member along said insulating member for said first charge storage region and forming a second isolating member along said insulating member for said last charge storage region.

14. The method of claim 1, wherein:
said first direction corresponds to a bit line axis for a NAND string of flash memory devices formed from said plurality of charge storage regions and said plurality of control gates;
said forming insulating members comprises, for each pair of charge storage regions and control gates adjacent in said first direction, forming a first insulating member along a first bit line side of a first charge storage region of said pair and a first bit line side of a first control gate of said pair, and forming a second insulating member along a first bit line side of a second charge storage region of said pair and a first bit line side of a second control gate of said pair; and
said forming conductive isolating members comprises, for said each pair, forming a single isolating member between said first insulating member and said second insulating member.

15. The method of claim 1, wherein forming a plurality of adjacent control gates consists of forming a plurality of word lines.

16. The method of claim 1, further comprising:
forming a plurality of adjacent word lines above said plurality of adjacent control gates, wherein each individual word line is connected to an individual one of said adjacent control gates.

17. The method of claim 1, wherein:
forming said conductive isolating members comprises depositing polysilicon.

18. The method of claim 17, wherein depositing polysilicon comprises depositing and etching said polysilicon to form isolating sidewalls having a thickness less than 50 angstroms.

19. The method of claim 1, wherein:
forming said insulating members comprises depositing at least one layer of oxide or nitride.

20. The method of claim 1, wherein:
forming said insulating members comprises depositing insulating sidewalls along said sides of said charge storage regions and control gates.

21. The method of claim 1, further comprising:
forming a dielectric layer above said substrate prior to forming said plurality of charge storage regions, said charge storage regions are formed above said dielectric layer.

22. The method of claim 1, wherein:
said control gates consist of one or more layers of a conductive material.

23. The method of claim 1, wherein:
said charge storage regions are conductive floating gate regions.

24. The method of claim 1, wherein:
said charge storage regions are dielectric charge storage regions.

25. The method of claim 1, wherein:
said charge storage regions are tailored dielectric layers.

26. The method of claim 1, wherein:
said plurality of charge storage regions and said plurality of control gates form storage elements for a NAND string.

27. The method of claim 26, wherein forming said plurality of charge storage regions and control gates is performed while fabricating an array of NAND flash memory devices.

28. The method of claim 1, wherein said plurality of charge storage regions and said plurality of control gates form multi-state flash memory devices.

29. A method of fabricating nonvolatile memory, comprising:
forming a plurality of charge storage regions above a substrate, said charge storage regions having two substantially parallel sides in a bit line direction;
forming a plurality of control gates above said charge storage regions;
forming first and second insulating layers between said bit line sides of charge storage regions adjacent in said bit line direction; and
forming at least one floating isolation shield between each of said first and second insulating layers.

30. The method of claim 29, wherein forming said at least one floating isolation shield between each of said first and second insulating layers includes depositing polysilicon to form a first isolating sidewall along each of said first insulating layers and a second isolating sidewall along each of said second insulating layers.

31. The method of claim 30, wherein forming first and second insulating layers includes forming each of said first and second insulating layers between bit line sides of control gates adjacent in said bit line direction, said bit line sides of said control gates are substantially co-planar with bit line sides of corresponding ones of said charge storage regions, said insulating layers extending from a lower surface level of said control gates to an upper surface level of said control gates.

32. The method of claim 31, wherein:
each of said first isolating sidewalls shields an adjacent charge storage region located across a corresponding first insulating layer; and
each of said second isolating sidewalls shields an adjacent charge storage region located across a corresponding second insulating layer.

33. The method of claim 32, wherein said first and second isolating sidewalls are capacitively coupled across said first and second insulating layers to corresponding ones of said control gates and corresponding ones of said charge storage regions, thereby increasing a coupling ratio between each of said control gates and a corresponding charge storage region.

34. The method of claim 29, wherein forming said at least one floating isolation shield between each of said first and second insulating layers comprises forming a single isolation shield between each of said first and second insulating layers.

35. The method of claim 29, wherein forming each of said at least one floating isolation shields includes forming insulation around substantially all of said at least one floating isolation shield such that no electrical connection is provided to said at least one floating isolation shield.

36. The method of claim 29, wherein:
forming said plurality of control gates includes forming a plurality of word lines extending in a word line direction substantially perpendicular to said bit line direction;
forming each of said first and second insulating layers includes forming said first insulating layer along a bit line side of a first word line and forming said second insulating member along a bit line side of a second word line adjacent to said first word line; and
forming said at least one floating isolation shield includes forming a first isolating sidewall extending in said word line direction along said first insulating layer and forming a second isolating sidewall extending in said word line direction along said second insulating layer.

37. The method of claim 29, wherein:
said plurality of charge storage regions form a NAND string of nonvolatile storage elements; and
said NAND string is electrically connected with a plurality of additional NAND strings to form an array of flash storage devices.

38. The method of claim 29, wherein:
said plurality of charge storage regions form a plurality of multi-state flash storage devices.

39. A method of fabricating nonvolatile memory, comprising:
forming charge storage regions above a substrate, said charge storage regions having two substantially parallel sides in a bit line direction;
forming control gates above said charge storage regions, said control gates having two substantially parallel sides in said bit line direction, each of said control gates is associated with an individual word line extending in a word line direction substantially perpendicular to said bit line direction;
forming insulation layers along said bit line sides of said charge storage regions;
forming said insulation layers along said bit lines sides of said control gates;
forming conductive isolation shields along said insulation layers, said isolation shields insulated from said charge storage regions and said control gates by said insulation layers; and
providing an electrical connection for each word line to one or more of said isolation shields adjacent to a charge storage region associated with said each word line.

40. The method of claim 39, wherein:
said charge storage regions are arranged in rows extending in said word line direction;
said conductive isolation shields include first and second isolation shields adjacent to each row of charge storage regions and on opposite sides thereof in said bit line direction; and
said electrical connection for each word line includes an electrical connection to said first and second conductive isolation shields adjacent to each row.

41. The method of claim 39, wherein:
said electrical connection for each word line is provided at a portion of said word line extending beyond a last charge storage region associated with said word line.

42. The method of claim 39, wherein:
said nonvolatile memory includes a first plurality of bit lines having substantially equally spacing therebetween and a second plurality of bit lines having substantially equal spacing therebetween;
a last bit line of said first plurality of bit lines is adjacent to a first bit line of said second plurality of bit lines, said last bit line and said first bit line have a larger spacing therebetween than said substantially equal spacing between bit lines of said first plurality and bit lines of said second plurality; and
said electrical connection for each word line is provided at said larger spacing between said last bit of said first plurality and said first bit line of said second plurality.

43. The method of claim 39, wherein:
said control gates are word lines.

44. The method of claim 39, wherein:
said charge storage regions form a plurality of multi-state flash storage devices.

45. The method of claim 39, wherein:
said charge storage regions form an array of NAND flash memory devices.
